(19) United States
(12) Patent Application Publication
(10) Pub. No.: US 2011/0236736 A1
(43) Pub. Date: Sep. 29, 2011

(54) ENERGY STORAGE DEVICE AND MANUFACTURING METHOD THEREOF

(75) Inventor: Mikio YUKAWA, Atsugi (JP)

(73) Assignee: SEMICONDUCTOR ENERGY LABORATORY CO., LTD., Atsugi-shi (JP)

(21) Appl. No.: 13/052,715

(22) Filed: Mar. 21, 2011

(30) Foreign Application Priority Data
Mar. 26, 2010 (JP) 2010-071589

(51) Int. Cl. H01M 10/48; H01G 9/00; H01M 4/26; H01M 10/04; C23C 14/34

(52) U.S. Cl. 429/90; 29/25.03; 29/623.1; 29/623.5; 204/192.17; 361/500

(57) ABSTRACT

An object is to provide an energy storage device capable of supplying stable voltage and easily detecting remaining capacity and charging capacity. The energy storage device includes a positive electrode, a negative electrode formed so as to face the positive electrode, and an electrolyte interposed between the positive electrode and the negative electrode, in which a discharging curve or a charging curve of the positive electrode has plateaus (also referred to as flat portions of the potential). Specifically, the discharging curve or the charging curve of the positive electrode has a plurality of plateaus, and positive electrode potential can be monitored in plural steps, whereby the remaining capacity and the charging capacity can be easily detected.

### BACKGROUND OF THE INVENTION

1. Field of the Invention

The present invention relates to an energy storage device and a manufacturing method thereof.

2. Description of the Related Art

With an increase in concern for the environmental issues, energy storage devices such as secondary batteries and electric double layer capacitors used for power supply for hybrid vehicles have been actively developed. As the energy storage devices, a lithium ion battery and a lithium ion capacitor having high energy performance have attracted attention. The lithium ion battery, which is compact but can store large electricity has been already mounted on a portable information terminal such as a mobile phone or a notebook personal computer, and has helped miniaturization of product.

The secondary battery and the electric double layer capacitor have a structure in which an electrolyte is provided between a positive electrode and a negative electrode. It is known that each of the positive electrode and negative electrode includes a current collector and an active material provided over the current collector. For example, in a lithium ion battery, a material capable of injection and extraction of lithium ions is used for each electrode as an active material, and an electrolyte is interposed between the electrodes (see Patent Document 1).

### REFERENCE

[Patent Document 1] International Publication WO 2006/049001 Pamphlet

### SUMMARY OF THE INVENTION

When an energy storage device as described above is discharged, an electric circuit that becomes a load may be broken or the electric circuit may malfunction by a change in voltage supplied to the electric circuit. Therefore, it is preferable that the energy storage device can supply constant voltage. That is, it is desirable that the energy storage device be stable in discharge characteristics.

Further, in the case where an energy storage device is charged, it is necessary to prevent excessive or insufficient charging. Thus, it is desirable that the energy storage device have stable charge characteristics.

Accordingly, it is an object of one embodiment of the present invention to provide an energy storage device having stable discharge characteristics. Further, it is another object of one embodiment of the present invention to provide an energy storage device having stable charge characteristics.

Furthermore, it is important to detect remaining capacity (remaining capacity up to the end of discharging) in the power storage device, and the remaining capacity can be detected by monitoring electrode potential of the energy storage device. However, it is difficult to detect the remaining capacity from the electrode potential while supply of stable voltage is required as mentioned above, when the electrode potential is not changed up to the end of the discharging.

Similarly, although it is important to detect charging capacity (capacity of the energy storage device after the device is charged by a predetermined time) in the energy storage device, it is difficult to detect the charging capacity from the electrode potential when the electrode potential is not changed up to the end of the charging.

Thus, it is an object of one embodiment of the present invention to provide an energy storage device which stabilizes charge and discharge characteristics and is capable of easily detecting remaining capacity and charging capacity.

The present invention provides an energy storage device including at least a positive electrode, and a negative electrode formed so as to face the positive electrode with an electrolyte interposed therebetween. The positive electrode includes a current collector and a film including an active material provided over the current collector. A charging curve or a discharging curve of the positive electrode has a flat portion of the potential. Specifically, the charging curve or the discharging curve of the positive electrode has a plurality of flat portions of the potential.

The film including an active material can be a thin film of the active material, a film in which particles of the active material are dispersed, or an aggregate of the particles of the active material.

One embodiment of the present invention is an energy storage device including a positive electrode and a negative electrode formed so as to face the positive electrode with an electrolyte interposed therebetween, in which a discharging curve or a charging curve of the positive electrode has a plurality of flat portions of the potential.

One embodiment of the present invention is a method for manufacturing an energy storage device including a positive electrode and a negative electrode formed so as to face the positive electrode with an electrolyte interposed therebetween, in which a process for manufacturing the positive electrode includes the steps of forming a film including an active material over a current collector using a LiFePO₄ target by a sputtering method and then performing heat treatment on the film including an active material, and in which a charging curve or a discharging curve of the positive electrode has a plurality of flat portions of the potential.

In the above manufacturing method, the heat treatment is preferably performed at greater than or equal to 450° C. and less than or equal to 700° C. for greater than or equal to 30 minutes and less than or equal to 40 hours.

Note that in this specification, the flat portion of the potential indicates a portion where the potential is changed while keeping flatness with respect to a change in capacity in charging and discharging curves in which the horizontal axis and the vertical axis indicate capacity and positive electrode potential, respectively. The flat portion of the potential is also referred to as a plateau.

By having the charging and discharging curves with the flat portions of the potential, an energy storage device having stable charge and discharge characteristics can be provided.

Further, by having the plurality of flat portions of the potential in the charging and discharging curves, an energy storage device which has stable charge and discharge characteristics and is capable of easily detecting remaining capacity and charging capacity can be provided.

### BRIEF DESCRIPTION OF THE DRAWINGS

FIG. 1 is a graph showing an example of charge and discharge characteristics of an energy storage device.

FIGS. 2A to 2C are views showing an example of a method for manufacturing an energy storage device.

FIGS. 3A to 3C are views showing an example of a structure of an energy storage device.

FIG. 4 is a graph showing an example of charge and discharge characteristics of an energy storage device.

FIG. 5 is a graph showing an example of a measurement result of X-ray diffraction.

### DETAILED DESCRIPTION OF THE INVENTION

Hereinafter, embodiments will be described in detail with reference to the accompanying drawings. However, since embodiments described below can be embodied in many different modes, it is easily understood by those skilled in the art that the mode and the detail can be variously changed without departing from the scope of the present invention. Therefore, the disclosed invention is not interpreted as being limited to the description of the embodiments below. In the drawings for explaining the embodiments, the same parts or parts having a similar function are denoted by the same reference numerals, and description of such parts is not repeated.

### Embodiment 1

In this embodiment, charge and discharge characteristics of an energy storage device is described.

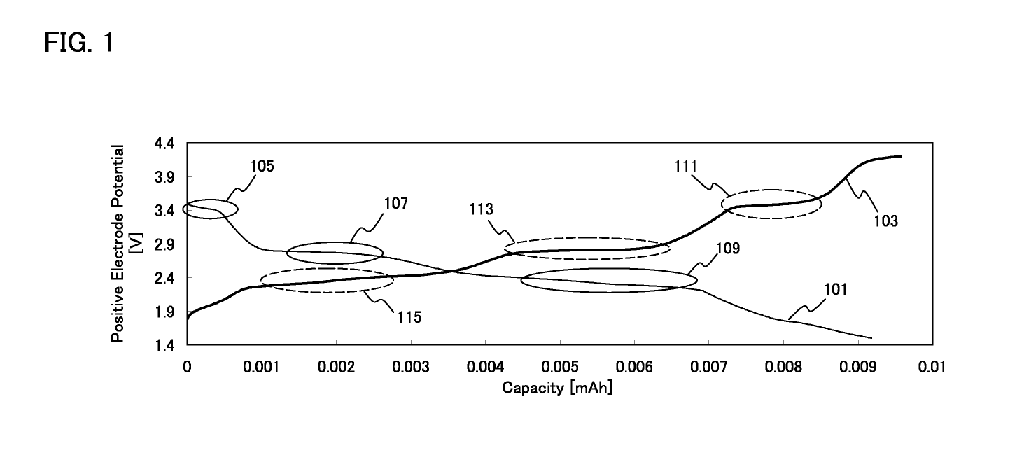

FIG. 1 shows charge and discharge characteristics of a positive electrode in an energy storage device, and reference numeral 101 denotes a discharging curve, and reference numeral 103 denotes a charging curve. The horizontal axis and the vertical axis indicate capacity and positive electrode potential, respectively.

In FIG. 1, the discharging curve 101 has flat portions of the potential (hereinafter also referred to as plateaus); thus, stable voltage can be supplied. Further, in the example in FIG. 1, the discharging curve 101 has plateaus in three steps (a plateau 105, a plateau 107, and a plateau 109).

The positive electrode potential of each plateau in the discharging curve 101 is as follows: the potential Vₘₐₓ of the plateau 105 is 3.5V; the potential V_{mid} of the plateau 107 is 2.9V; and the potential Vₘᵢₙ of the plateau 109 is 2.4V.

Since the discharging curve 101 has the plateaus in three steps, the positive electrode potential can be monitored in three steps. By monitoring the positive electrode potential, the remaining capacity of the energy storage device can be easily detected until the end of the discharging.

Use of the energy storage device can be increased by changing its application depending on the remaining capacity of the energy storage device. In FIG. 1, in the case where high potential is required, 3.5V is used; in the case where low potential is required, 2.4V is used; and in the case where the potential intermediate therebetween is required, 2.9V is used.

Further, the charging curve 103 also has plateaus; thus, stable voltage can be supplied. Further, in the example in FIG. 1, the charging curve 103 has plateaus in three steps (a plateau 111, a plateau 113, and a plateau 115).

The positive electrode potential of each plateau in the charging curve 103 is as follows: the potential Vₘₐₓ of the plateau 111 is 3.5V; the potential V_{mid} of the plateau 113 is 2.9V; and the potential Vₘᵢₙ of the plateau 115 is 2.4V.

The charging curve 103 has the plateaus in three steps; thus, the positive electrode potential can be monitored in three steps. By monitoring the positive electrode potential, charging capacity can be easily detected.

In the case where low potential is used, it is not necessary to complete charging; thus, charging time can be shortened and deterioration of the energy storage device due to the charging can be suppressed. In FIG. 1, in the case where high potential is required, the energy storage device is charged to 3.5V; in the case where low potential is required, the energy storage device is charged to 2.4V; and in the case where the potential intermediate therebetween is required, the energy storage device is charged to 2.9V.

Note that in the plateaus in three steps in the discharging curve 101 and charging curve 103, it is preferable that Vₘₐₓ, V_{mid}, and Vₘᵢₙ satisfy 0.3≦Vₘᵢₙ/Vₘₐₓ≦0.8, and −0.3≦2×(V_{mid}−V_{M})/(Vₘₐₓ−Vₘᵢₙ)≦0.3. By satisfying such relations, the potential can be accurately monitored in three steps. Note that V_{M} is the potential intermediate between Vₘₐₓ and Vₘᵢₙ, and is (Vₘₐₓ+Vₘᵢₙ)/2.

Further, in the case where a plurality of energy storage devices is connected in series, for example, there may be great difference between Vₘₐₓ and Vₘᵢₙ, for example the difference is greater than or equal to 5V. In that case, the plateau with V_{mid} may be placed near the plateau with Vₘₐₓ. In such a case, it is preferable that Vₘₐₓ, and V_{mid} satisfy 0.05V≦Vₘₐₓ−V_{mid}≦2V, preferably 0.05V≦Vₘₐₓ−V_{mid}≦0.5V. Accordingly, the potential can be monitored in plural steps near the plateau with Vₘₐₓ. Alternatively, the plateau with V_{mid} may be placed near the plateau with Vₘᵢₙ. In such a case, it is preferable that Vₘᵢₙ, and V_{mid} satisfy 0.05V≦V_{mid}−Vₘᵢₙ≦2V, preferably 0.05V≦V_{mid}−Vₘᵢₙ≦0.5V. Accordingly, the potential can be monitored in plural steps near the plateau with Vₘᵢₙ.

Although the characteristics of the positive electrode are described in this embodiment; this description can be applied to the characteristics of the negative electrode. However, in the case of the negative electrode, its characteristics are not stable because of the influence of, for example, formation of an alloy containing a negative electrode material; thus, there is a possibility that the potential can not be monitored accurately. Therefore, with the structure having the plateaus in the charging and discharging curves of the positive electrode, charge and discharge characteristics of the energy storage device can be stabilized. The above mentioned alloy can be an alloy of a current collector and an active material, an alloy of a current collector and an electrolyte, an alloy of a current collector, an active material, and an electrolyte, or the In addition, the energy storage device may have a detecting portion for monitoring the potential. The detecting portion detects the potential of plateaus in three steps, and outputs respective detection signals in the three steps. As one example, a structure in which a lamp is turned on to emit light in any one of three colors, such as red, green, and blue can be given in accordance with the steps. With such a structure, the remaining capacity and the charging capacity can be easily detected.

Further, an example of having the plateaus in three steps is described in this embodiment; however, the discharging curve and charging curve may have plateaus in two steps or plateaus in four or more steps. That is, a plurality of plateaus may be included so that potential can be monitored.

With such charge and discharge characteristics as described above, an energy storage device capable of supplying stable voltage in plural steps and easily detecting remaining capacity and charging capacity can be provided.

This embodiment can be combined with any of the other embodiments as appropriate.

### Embodiment 2

In this embodiment, an example of a method for manufacturing an energy storage device which can achieve charge and discharge characteristics as described in Embodiment 1 is illustrated.

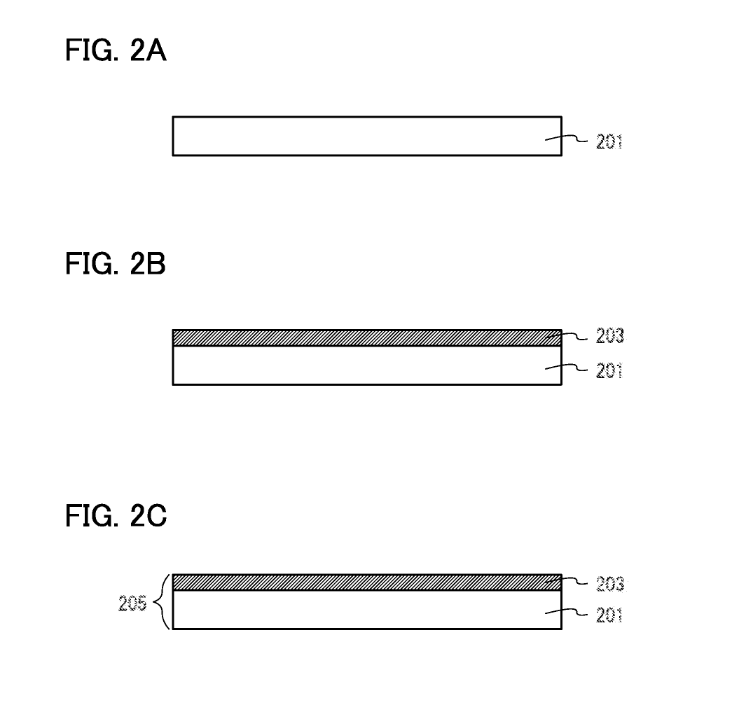

FIGS. 2A to 2C illustrate an example of a method for manufacturing a positive electrode of a lithium secondary battery.

First, the current collector 201 is prepared (FIG. 2A).

There is no particular limitation on a material used for the current collector 201; however, a material having high conductivity such as platinum, aluminum, copper, or titanium can be used. In this embodiment, titanium is used.

Next, a film 203 including an active material is formed over the current collector 201 (FIG. 2B).

Lithium oxide is preferably used for a material for the active material included in the film 203 including an active material. Lithium has high ionization tendency and a small atomic radius, whereby injection into and extraction from a positive electrode can be performed stably. Therefore, the charge and discharge characteristics of the positive electrode can be stabilized. For example, a compound represented by the following chemical formula can be employed: LiₓM_{y}O_{z} (x, y, and z are positive real numbers) such as lithium cobalt oxide (LiCoO₂), lithium manganese oxide (LiMn₂O₄), or lithium iron phosphate (LiFePO₄). Here, M represents one material or a plurality of materials. In the case where M represents one material, M is preferably a metal material. In the case where M represents a plurality of materials, M may be a combination of plural metal materials or a combination of a metal material and a non-metal material.

As a method for manufacturing the film 203 including an active material, a dry process such as a PVD method (e.g., a sputtering method), a vacuum evaporation method, or a CVD method (e.g., a plasma CVD method) can be used. By using the dry process, the film 203 including an active material can be made uniform and thin. Thus, the charge and discharge characteristics of the positive electrode can be stabilized.

Further, as a method for manufacturing the film 203 including an active material, a wet process such as a coating method may be employed. However, in the case of employing the wet process, particles of the active material are dispersed and uniformity may be impaired. Thus, as in this embodiment, the dry process is preferably employed.

In this embodiment, lithium iron phosphate (the film 203 including an active material) with a thickness of 10 nm to 3 μm is formed using a LiFePO₄ target by a sputtering method. Here, the film 203 including an active material is formed to a thickness of 100 nm.

As described above, the positive electrode 205 is manufactured (FIG. 2C).

Note that heat treatment may be performed on the film 203 including an active material. For example, in the case where the active material is lithium iron phosphate, heat treatment crystallizes the film 203 including an active material or can enhance the crystallinity of the film 203 including an active material.

The temperature of the heat treatment is preferably set at 450° C. to 700° C. inclusive. In addition, the heat treatment is performed for 30 minutes to 40 hours inclusive, preferably 2 hours to 10 hours inclusive. Further, the heat treatment is preferably performed in a rare gas atmosphere, a nitrogen atmosphere, or the like; accordingly, the film 203 including an active material can be uniform. In this embodiment, the heat treatment is performed at 600° C. for 4 hours in a nitrogen atmosphere.

Then, an electrolyte, and a negative electrode which is formed so as to face the positive electrode with the electrolyte interposed therebetween are formed, thereby obtaining the energy storage device.

The positive electrode 205 of the lithium secondary battery thus manufactured has the charge and discharge characteristics as described in Embodiment 1, whereby stable voltage can be supplied in plural steps, and remaining capacity and charging capacity of the lithium secondary battery can be easily detected.

This embodiment can be combined with any of the other embodiments as appropriate.

### Embodiment 3

In this embodiment, an example of the structure of the energy storage device is described.

An example of the structure of the positive electrode used in the energy storage device is described with reference to FIG. 2C.

The positive electrode 205 includes the current collector 201 and the film 203 including an active material formed over the current collector 201.

The material described in Embodiment 2 can be used as a material for the current collector 201. In this embodiment, titanium is used.

The material described in Embodiment 2 can be used for a material for the active material. In this embodiment, lithium iron phosphate with a thickness of 100 nm is used.

An example of the structure of the energy storage device using the above positive electrode is described.

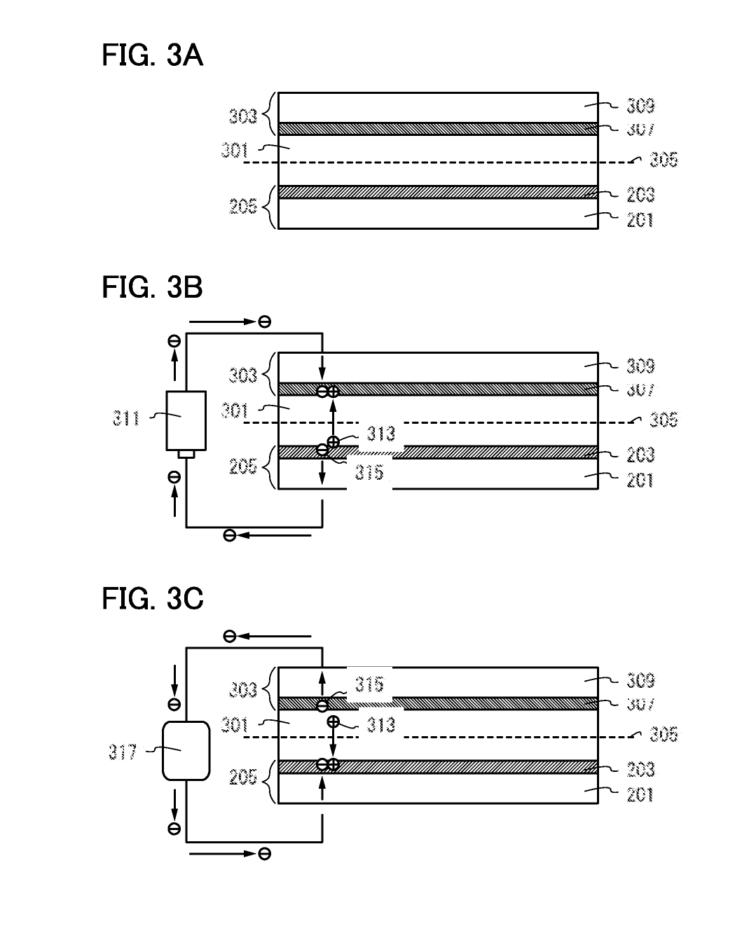

FIGS. 3A to 3C are an example of the energy storage device, which includes the positive electrode 205, a negative electrode 303 provided so as to face the positive electrode 205, and an electrolyte 301 interposed therebetween, and includes a separator 305 between the positive electrode 205 and the negative electrode 303.

The electrolyte 301 functions to conduct lithium ions. In other words, lithium ions move between the positive electrode 205 and the negative electrode 303 through the electrolyte 301. As a material for the electrolyte 301, a liquid or a solid can be used. The material for the electrolyte 301 can be changed as appropriate in accordance with the active material and the like.

In the case where the material for the electrolyte 301 is a liquid, the liquid includes a solvent and a solute (salt) dissolved in the solvent. As the solvent, any of cyclic carbonates such as propylene carbonate and ethylene carbonate, or chain-like carbonates such as dimethyl carbonate and diethyl carbonate can be used. As the solute (salt), for example, a solute (salt) including one or two or more kinds of light metal salts (lithium salt and the like) such as LiPF₆, LiBF₄, or LiTFSA can be used.

In the case where the material for the electrolyte 301 is a solid, Li₃PO₄, LiₓPO_{y}N_{z} (x, y, and z are positive real numbers) to which nitrogen is mixed into Li₃PO₄, Li₂S—SiS₂, Li₂S—P₂S₃, Li₂S—B₂S₃ or the like can be used. Further, the above material doped with lithium halide such as LiI, the above material doped with lithium oxoate such as Li₃PO₄, or the like can be used.

The separator 305 prevents contact between the positive electrode 205 and the negative electrode 303 and allows lithium ions to pass therethrough. As a material for the separator 305, for example, paper, nonwoven fabric, a glass fiber, a synthetic fiber such as nylon (polyamide), vinylon (a polyvinyl alcohol based fiber that is also referred to as vinalon), polypropylene, polyester, acrylic, polyolefin, or polyurethane, etc. may be used. However, a material which is not dissolved in the electrolyte 301 should be selected. Note that when a solid electrolyte is used as the electrolyte 301, the separator 305 can be omitted.

The negative electrode 303 includes a current collector 309 and a film 307 including an active material. There is no particular limitation on a material used for the current collector 309; however, a material having high conductivity such as platinum, copper, or titanium can be used. There is no particular limitation on a material used for the active material, a lithium metal, a carbon material such as graphite, silicon, or the like may be used. Note that a lithium metal or the like can be used alone. In this embodiment, the lithium metal with a thickness of 0.6 mm is used as the negative electrode 303.

Next, an example of charging and discharging in the case where a lithium secondary battery is used as the energy storage device is described.

As illustrated in FIG. 3B, charging is performed by connecting a power source 311 between the positive electrode 205 and the negative electrode 303. When voltage is applied from the power source 311, lithium in the positive electrode 205 is ionized and a lithium ion 313 is extracted from the positive electrode 205, and an electron 315 is generated. The lithium ion 313 moves to the negative electrode 303 through the electrolyte 301. The electron 315 moves to the negative electrode 303 through the power source 311. Then, the lithium ion 313 receives the electron 315 in the negative electrode 303 and lithium is injected into the negative electrode 303.

On the other hand, as illustrated in FIG. 3C, discharging is performed by connecting a load 317 between the positive electrode 205 and the negative electrode 303. Lithium in the negative electrode 303 is ionized, and the lithium ion 313 is desorbed from the negative electrode 303, thereby generating the electron 315. The lithium ion 313 moves to the positive electrode 205 through the electrolyte 301. The electron 315 moves to the positive electrode 205 through the load 317. Then, the lithium ion 313 receives the electron 315 in the positive electrode 205 and lithium is injected into the positive electrode 205.

As described above, charging and discharging are performed by the movement of the lithium ion between the positive electrode 205 and the negative electrode 303. Here, the positive electrode 205 of the energy storage device has the charge and discharge characteristics as illustrated in Embodiment 1, whereby stable voltage can be supplied in plural steps, and remaining capacity and charging capacity of the lithium secondary battery can be easily detected.

This embodiment can be combined with any of the other embodiments as appropriate.

### Example 1

In this example, the method for manufacturing the energy storage device and the charge and discharge characteristics are described specifically.

First, description is made of a sample of an energy storage device which was manufactured. As the sample, a 2032 type coin-like battery including a positive electrode, a negative electrode, and a separator containing an electrolyte between the positive electrode and the negative electrode was formed. As the positive electrode of the sample, a film including an active material was formed over titanium. As the negative electrode, a lithium metal was formed. As the separator, polypropylene (PP) was formed. As the electrolyte, a mixed solution of ethylene carbonate (EC) and diethyl carbonate (DEC) in which LiPF₆ was dissolved was used.

The film including an active material in the positive electrode was formed by a sputtering method using a LiFePO₄ target having an olivine structure under the following conditions: the power of an RF power source was 700 W; the pressure was 0.1 Pa; and the atmosphere was an argon atmosphere.

Next, heat treatment was performed on the film including an active material. The heat treatment was performed in a nitrogen atmosphere at 600° C. for 4 hours.

Using the manufactured sample, charge and discharge test was performed (with a charge/discharge tester, TOSCAT-3100, TOYO SYSTEM CO., LTD). The voltage for the measurement was set in the range of 1.5 V to 4.2 V, and the current for the measurement was set to a constant current of 0.001 mA. In the charge and discharge test, constant-current charge, a two-hour pause, constant-current discharge, and a two-hour pause were performed in this order, in which voltage (V) and capacity (mAh) were measured during the charge, during the pause after the charge, during the discharge, and during the pause after the discharge.

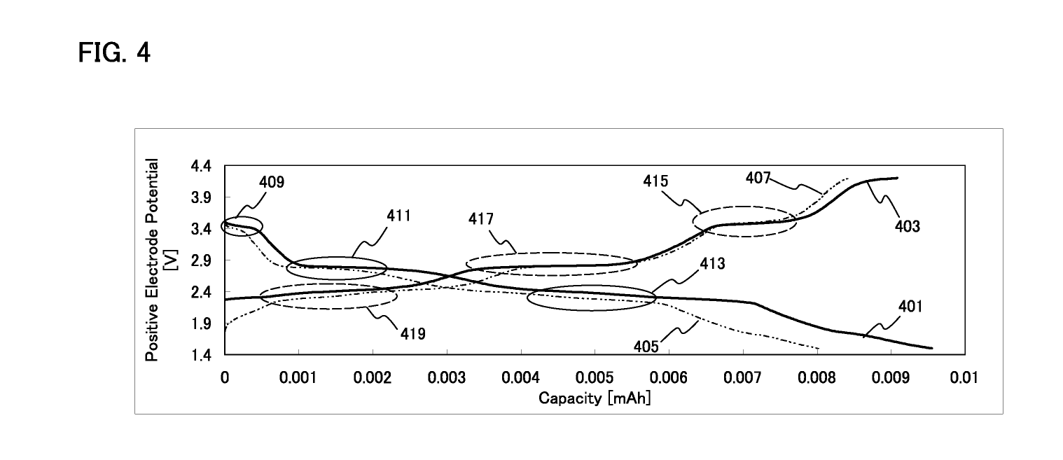

The results of the measurement by the charge and discharge test are shown in FIG. 4. FIG. 4 shows charge and discharge characteristics of the energy storage device, in which the vertical axis and the horizontal axis indicate positive electrode potential (V) and capacity (mAh), respectively.

FIG. 4 shows a discharging curve 401 and charging curve 403 at a 0.1 C rate, and a discharging curve 405 and charging curve 407 at a 0.2 C rate. Here, a C rate represents a current value in charging and discharging. A 1 C rate refers to the amount of current with which the battery is discharged completely for 1 hour. For example, when full capacity of the battery is 2.2 [A/h], 1 C is 2.2 [A], and an n C (n is a positive integer) is 2.2 n [A].

From the result in FIG. 4, as for the charge characteristics of the positive electrode, plateaus in three steps (a plateau 409, a plateau 411, and a plateau 413) can be confirmed at the both 0.1 C rate and 0.2 C rate. Further, as for the discharge characteristics of the positive electrode, plateaus in three steps (a plateau 415, a plateau 417, and a plateau 419) can be confirmed at the both 0.1 C rate and 0.2 C rate.

The potential of the plateaus in three steps in the discharging curve 401 at the 0.1 C rate is as follows: Vₘₐₓ=3.5V; V_{mid}=2.9V; Vₘᵢₙ=2.4V; Vₘᵢₙ/Vₘₐₓ=0.69; and 2×V_{mid}−V_{M})/(Vₘₐₓ−Vₘᵢₙ)=−0.09.

Further, the potential of the plateaus in three steps in the charging curve 403 at the 0.1 C rate is as follows: Vₘₐₓ=3.5V; V_{mid}=2.9V; Vₘᵢₙ=2.4V; Vₘᵢₙ/Vₘₐₓ=0.69; and 2×(V_{mid}−V_{M})/(Vₘₐₓ−Vₘᵢₙ)=−0.091.

Furthermore, the potential of the plateaus in three steps in the discharging curve 405 at the 0.2 C rate is as follows: Vₘₐₓ=3.4V; V_{mid}=2.8V; Vₘᵢₙ=2.3V; Vₘᵢₙ/Vₘₐₓ=0.68; and 2×(V_{mid}−V_{M})/(Vₘₐₓ−Vₘᵢₙ)=−0.091.

Furthermore, the potential of the plateaus in three steps in the charging curve 407 at the 0.2 C rate is as follows: Vₘₐₓ=3.5V; V_{mid}=2.9V; Vₘᵢₙ=2.3V; Vₘᵢₙ/Vₘₐₓ=0.66; and 2×(V_{mid}−V_{M})/(Vₘₐₓ−Vₘᵢₙ)=0.

These calculation results satisfy 0.3≦Vₘᵢₙ/Vₘₐₓ≦0.8, and −0.3≦2×V_{M})≦0.3, which are described in Embodiment 1.

As described above, the manufactured sample has the plateaus in three steps and stable voltage can be supplied. Further, the positive electrode potential can be monitored in three steps, and remaining capacity and charging capacity of the lithium secondary battery can be easily detected.

Here, a film including an active material in this example is considered. The film including an active material in this example (formed using a LiFePO₄ target having an olivine structure with an RF power source of 700 W and a pressure of 0.1 Pa in an argon atmosphere by a sputtering method) was subjected to measurement using X-ray photoelectron spectroscopy (XPS) and inductively coupled plasma mass spectrometry (ICP-MS), just after being formed.

From the results of the XPS and the ICP-MS, the composition ratio in the film including an active material was estimated as follows: Li:Fe:P:O=9.3:11.9:8.6:61.2. Further, from the peak of 2p orbital of Fe in XPS, it was recognized that the valence of Fe was mainly two at this stage.

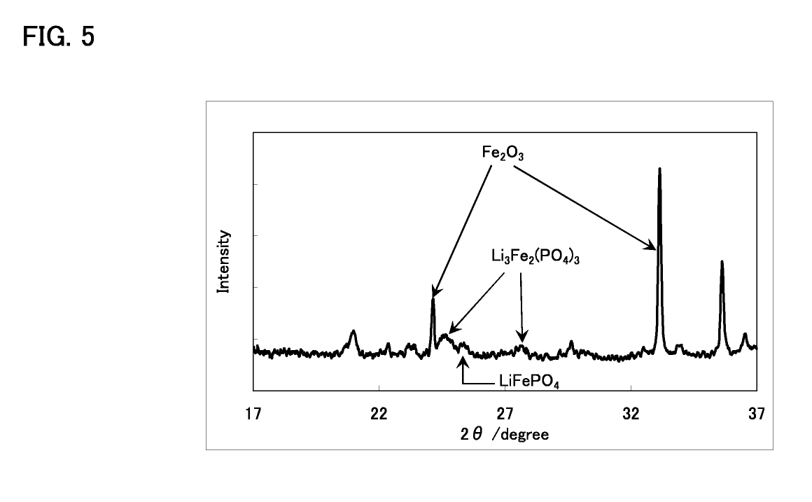

Furthermore, after the film is formed, measurement using X-ray diffraction (XRD) was performed on the film including an active material after the heat treatment (at 600° C. for four hours in a nitrogen atmosphere). An XRD measurement result is shown in FIG. 5.

From the result in FIG. 5, peaks of Fe₂O₃, peaks of Nasicon-type Li₃Fe₂(PO₄)₃, and peaks of olivine-type LiFePO₄ can be confirmed in the film including an active material after the heat treatment. Therefore, it was considered that trivalent Fe was included at this stage. From the result in FIG. 5, it is found that the film including an active material also includes Fe, whose valence is changed from two to three, and the film including an active material is oxidized by the heat treatment after the film is formed.

This application is based on Japanese Patent Application serial no. 2010-071589 filed with Japan Patent Office on Mar. 26, 2010, the entire contents of which are hereby incorporated by reference.

What is claimed is:

1. An energy storage device comprising:
a positive electrode;
a negative electrode formed so as to face the positive electrode; and
an electrolyte interposed between the positive electrode and the negative electrode,
wherein a discharging curve of the positive electrode has a plurality of plateaus.

2. The energy storage device according to claim 1, wherein the positive electrode comprises a current collector and an active material.

3. The energy storage device according to claim 1, wherein the negative electrode comprises a current collector and an active material.

4. The energy storage device according to claim 1 further comprising a separator between the positive electrode and the negative electrode.

5. An energy storage device comprising:
a positive electrode;
a negative electrode formed so as to face the positive electrode; and
an electrolyte interposed between the positive electrode and the negative electrode,
wherein a charging curve of the positive electrode has a plurality of plateaus.

6. The energy storage device according to claim 5, wherein the positive electrode comprises a current collector and an active material.

7. The energy storage device according to claim 5, wherein the negative electrode comprises a current collector and an active material.

8. The energy storage device according to claim 5 further comprising a separator between the positive electrode and the negative electrode.

9. A method for manufacturing an energy storage device comprising: a positive electrode; a negative electrode formed so as to face the positive electrode; and an electrolyte interposed between the positive electrode and the negative electrode,
wherein a process for manufacturing the positive electrode comprises:
forming a film including an active material over a current collector using a LiFePO₄ target by a sputtering method; and
performing a heat treatment on the film including the active material, and
wherein a discharging curve of the positive electrode has a plurality of plateaus.

10. The method for manufacturing the energy storage device according to claim 9, wherein the heat treatment is performed at greater than or equal to 450° C. and less than or equal to 700° C. for greater than or equal to 30 minutes and less than or equal to 40 hours.

11. The method for manufacturing the energy storage device according to claim 9, wherein the active material after the heat treatment includes trivalent Fe.

12. A method for manufacturing an energy storage device comprising: a positive electrode; a negative electrode formed so as to face the positive electrode; and an electrolyte interposed between the positive electrode and the negative electrode,
wherein a process for manufacturing the positive electrode comprises:
forming a film including an active material over a current collector using a LiFePO₄ target by a sputtering method; and
performing a heat treatment on the film including the active material, and
wherein a charging curve of the positive electrode has a plurality of plateaus.

13. The method for manufacturing the energy storage device according to claim 12, wherein the heat treatment is performed at greater than or equal to 450° C. and less than or equal to 700° C. for greater than or equal to 30 minutes and less than or equal to 40 hours.

14. The method for manufacturing the energy storage device according to claim 12, wherein the active material after the heat treatment includes trivalent Fe.
